(19) United States
(12) Patent Application Publication
(10) Pub. No.: US 2025/0126769 A1
(43) Pub. Date: Apr. 17, 2025

(54) MEMORY DEVICES WITH DIFFERENTLY SIZED ACTIVE REGIONS IN PERIPHERY CIRCUITS

(71) Applicant: Taiwan Semiconductor Manufacturing Company, Ltd., Hsinchu (TW)

(72) Inventors: Chia-Hao Pao, Kaohsiung City (TW); Ping-Wei Wang, Hsin-Chu (TW); Lien-Jung Hung, Taipei (TW); Feng-Ming Chang, Hsinchu County (TW); Yu-Kuan Lin, Taipei City (TW); Jui-Wen Chang, Hsinchu (TW)

(21) Appl. No.: 18/412,129

(22) Filed: Jan. 12, 2024

Related U.S. Application Data
(60) Provisional application No. 63/590,938, filed on Oct. 17, 2023.

(51) Int. Cl. H10B 10/00; H01L 29/06; H01L 29/423; H01L 29/66; H01L 29/775; H01L 29/78; H01L 29/786

(52) U.S. Cl. CPC H10B 10/125; H10B 10/18; H10D 30/014; H10D 30/024; H10D 30/43; H10D 30/6211; H10D 30/6735; H10D 30/6757; H10D 62/121

(57) ABSTRACT

An electronic memory device includes a memory-cell circuit. The electronic memory device also includes a non-memory-cell circuit. The non-memory cell circuit includes an active region. The active region extends in a first direction in a top view. The active region includes a first segment and a second segment. The first segment has a first dimension measured in a second direction in the top view. The second segment has a second dimension measured in the second direction different from the first direction in the top view. The second dimension is different from the first dimension.

### PRIORITY

This application claims the priority of U.S. Provisional Application Ser. No. 63/590,938, filed Oct. 17, 2023, entitled “Memory Devices With Jogs In Periphery Circuits”, the entire disclosure of which is incorporated herein by reference.

### BACKGROUND

The electronics industry has experienced an ever-increasing demand for smaller and faster electronic devices which are simultaneously able to support a greater number of increasingly complex and sophisticated functions. Accordingly, there is a continuing trend in the semiconductor industry to manufacture low-cost, high-performance, and low-power integrated circuits (ICs). Thus far, these goals have been achieved in large part by scaling down semiconductor IC dimensions (e.g., minimum feature size) and thereby improving production efficiency and lowering associated costs. However, such scaling has also introduced increased complexity to the semiconductor manufacturing process. Thus, the realization of continued advances in semiconductor ICs and devices calls for similar advances in semiconductor manufacturing processes and technology.

As integrated circuit devices get scaled down, the geometric patterns of an active region may become more influential. If the active regions have substantially rectangular shapes, certain device performance metrics may not be optimized. Therefore, while the IC layout designs for IC device designs are generally adequate for their intended purposes, they are not satisfactory in all aspects.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1A is a diagrammatic perspective view of a semiconductor device.

FIG. 1B is a diagrammatic top view of a semiconductor device.

FIG. 1C is a diagrammatic perspective view of a semiconductor device.

FIG. 2 is a circuit schematic of an SRAM cell.

FIG. 3 is a block diagram of a top view of a memory device according to various aspects of the present disclosure.

FIGS. 4-11 are top views of a portion of a memory device that contain active regions according to various aspects of the present disclosure.

FIGS. 12-14 illustrate the revision of an original IC layout design to generate a revised IC layout design according to various embodiments of the present disclosure.

FIG. 15 is a block diagram of a semiconductor fabrication system.

FIG. 16 is a flowchart illustrating a method of revising an IC layout design.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

In addition, the present disclosure may repeat reference numerals and/or letters in the various examples. This repetition is for the purpose of simplicity and clarity and does not in itself dictate a relationship between the various embodiments and/or configurations discussed. Moreover, the formation of a feature on, connected to, and/or coupled to another feature in the present disclosure that follows may include embodiments in which the features are formed in direct contact, and may also include embodiments in which additional features may be formed interposing the features, such that the features may not be in direct contact. In addition, spatially relative terms, for example, “lower,” “upper,” “horizontal,” “vertical,” “above,” “over,” “below,” “beneath,” “up,” “down,” “top,” “bottom,” etc., as well as derivatives thereof (e.g., “horizontally,” “downwardly,” “upwardly,” etc.) are used for ease of the present disclosure of one features relationship to another feature. The spatially relative terms are intended to cover different orientations of the device including the features. Still further, when a number or a range of numbers is described with “about,” “approximate,” and the like, the term is intended to encompass numbers that are within a reasonable range including the number described, such as within +/−10% of the number described or other values as understood by person skilled in the art. For example, the term “about 5 nm” encompasses the dimension range from 4.5 nm to 5.5 nm.

The present disclosure is generally related to semiconductor devices, and more particularly to field-effect transistors (FETs), such as three-dimensional fin-shaped FETs (FinFETs) or gate-all-around (GAA) devices. In that regard, a FinFET device is a fin-like field-effect transistor device, and a GAA device is a multi-channel field-effect transistor device. FinFET devices and GAA devices have both been gaining popularity recently in the semiconductor industry, since they offer several advantages over traditional Metal-Oxide Semiconductor Field Effect Transistor (MOSFET) devices (e.g., “planar” transistor devices). These advantages may include better chip area efficiency, improved carrier mobility, and fabrication processing that is compatible with the fabrication processing of planar devices. Thus, it may be desirable to design an integrated circuit (IC) chip using FinFET devices or GAA devices for a portion of, or the entire IC chip.

However, in spite of the advantages offered by the FinFET devices and/or GAA devices, certain challenges may still remain in IC applications in which FinFET or GAA devices are implemented. For example, conventional semiconductor fabrication does not take into account that transistors in different applications may have specific concerns and should be optimized differently based on their specific concerns. For example, the device speed of transistors may be a greater concern in some IC circuits, while leakage of transistors may be a greater concern in some other IC circuits. Unfortunately, these concerns have not been adequately addressed. For example, while the geometries of active regions could have a meaningful impact on the device speed and/or the leakage, the geometries of active regions in many different types of circuits have been configured with a “one-size-fits-all” approach. As a result, device performance has not been sufficiently optimized.

To address the issues discussed above, the present disclosure configures the shapes and/or sizes of the active regions differently for transistors based on the type of IC circuit in which they are implemented. For example, for IC circuits that place a greater emphasis on device speed, the corresponding active regions may be enlarged to help achieve a faster device speed. For IC circuits that place a greater emphasis on reducing leakage, the corresponding active regions may be shrunk to help reduce the leakage. As such, even when the different IC circuits are formed using the same set of fabrication processes on the same wafer, their performances may be individually optimized to address their unique concerns.

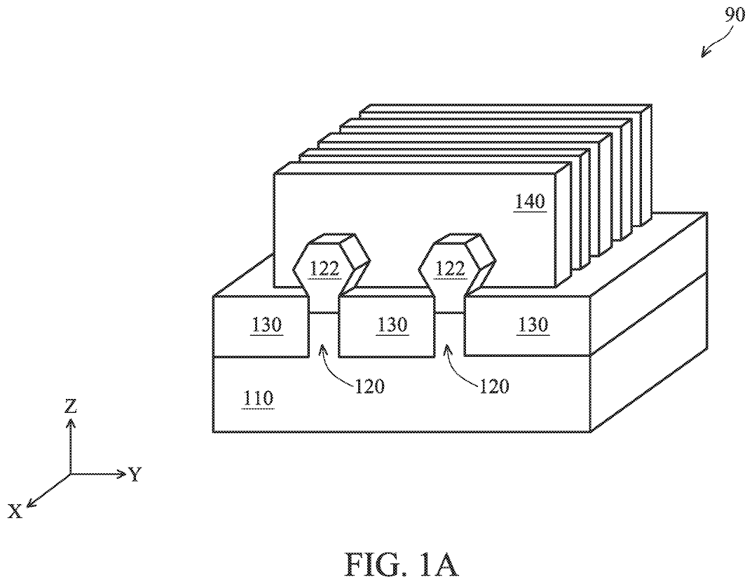

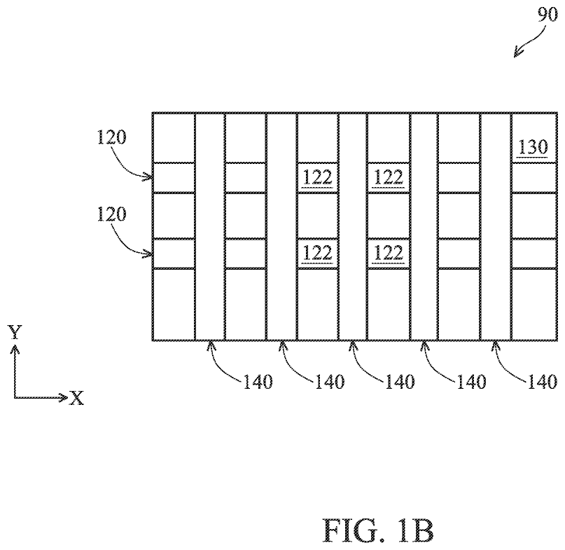

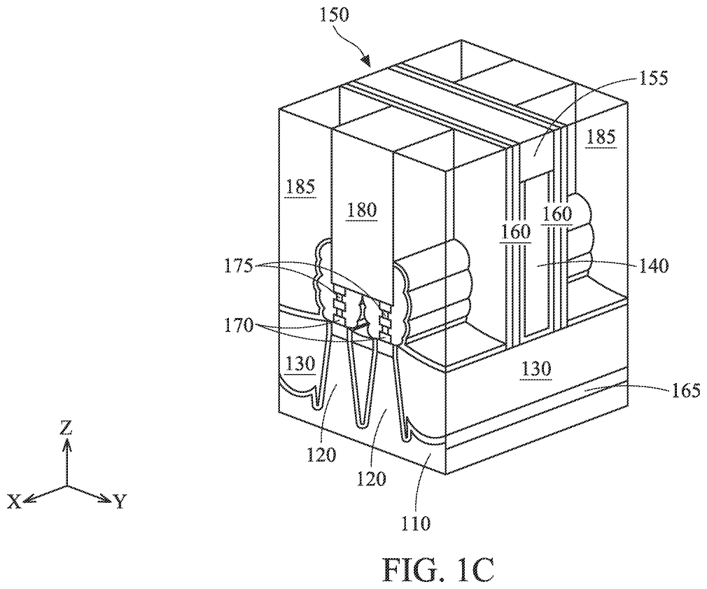

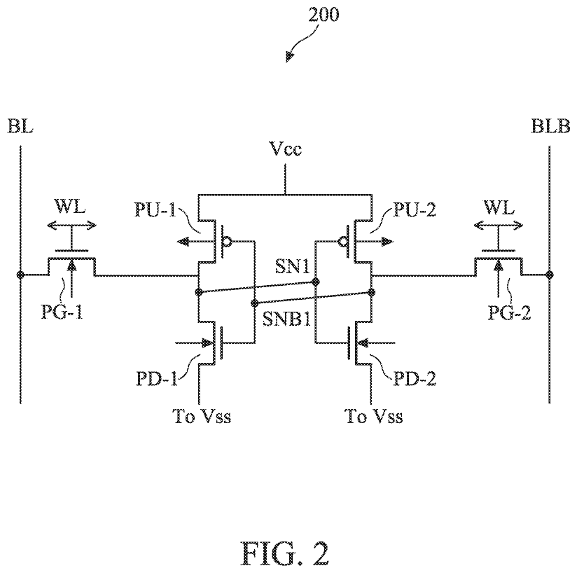

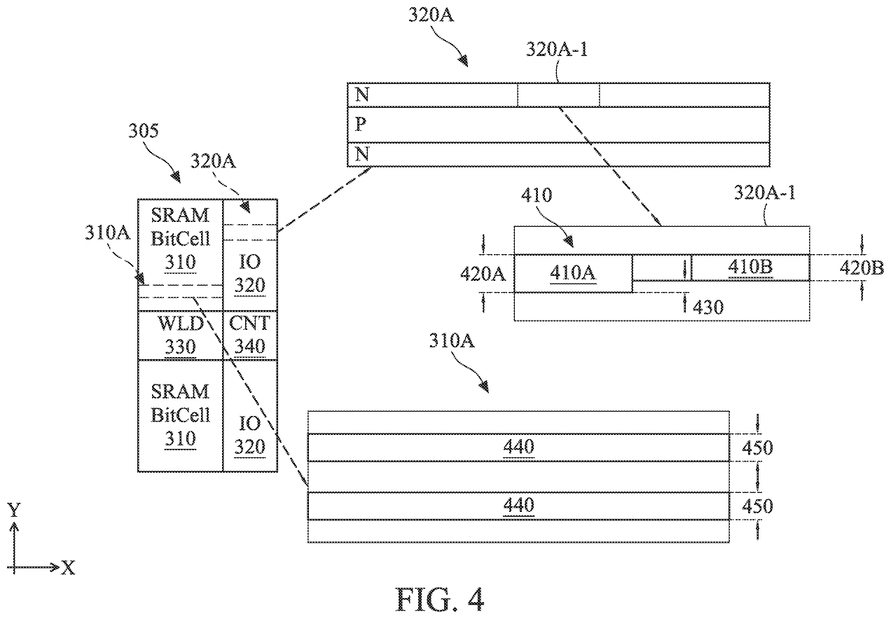

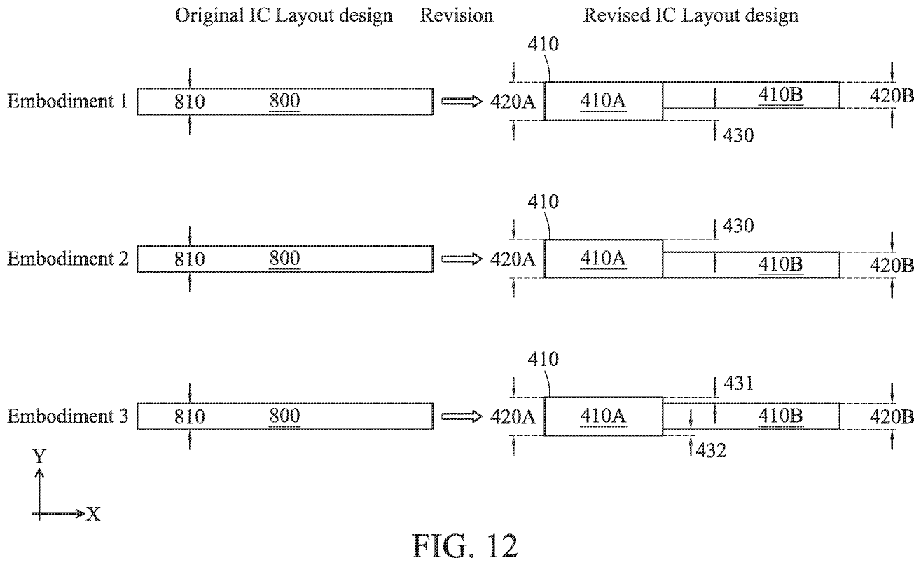

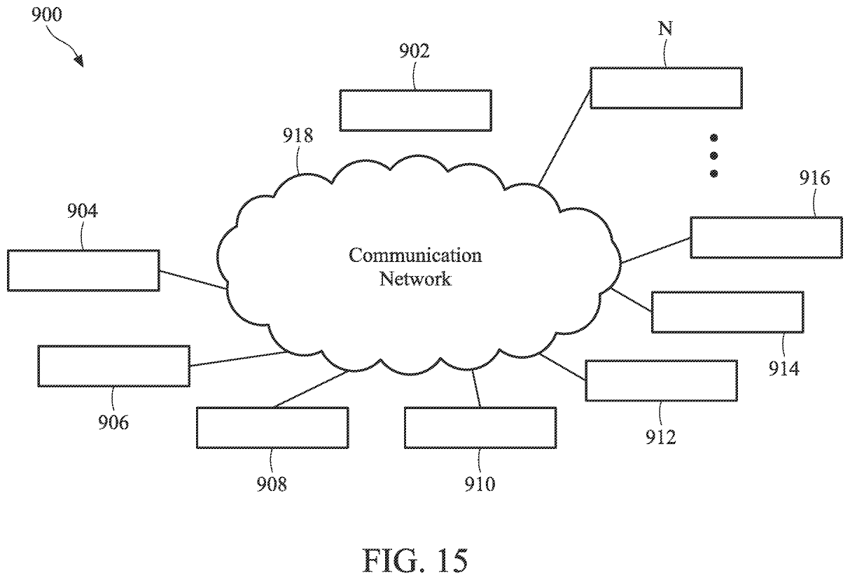

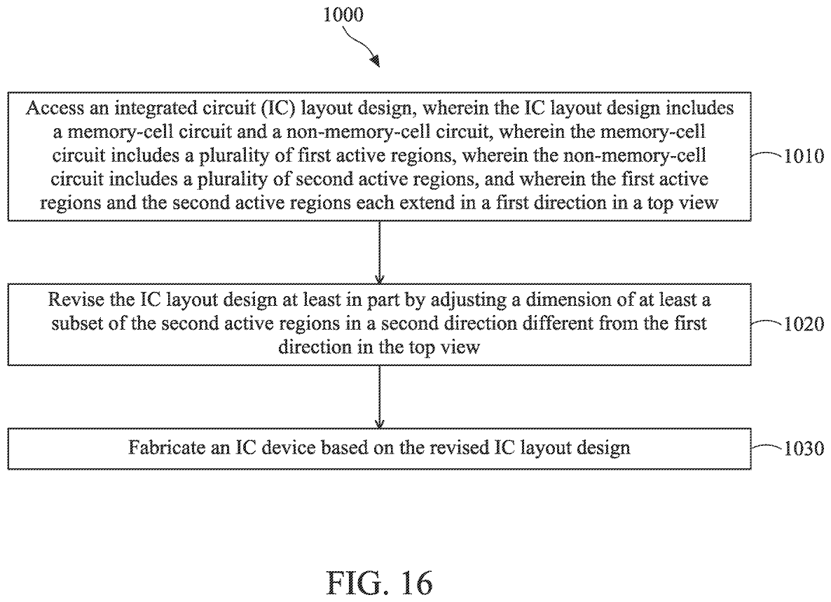

The various aspects of the present disclosure are now discussed in greater detail with reference to FIGS. 1A-1C and 2-16. In more detail, FIGS. 1A-1C will describe the basic structures of example FinFET and GAA devices. FIG. 2 will describe an example electronic memory device. Fig is a block diagram of a top view of a memory device according to various aspects of the present disclosure. FIGS. 4-11 are top views of a portion of a memory device that contain active regions according to various aspects of the present disclosure. FIGS. 12-14 illustrate the revision of an original IC layout design to generate a revised IC layout design according to various embodiments of the present disclosure. FIG. 15 is a block diagram of a semiconductor fabrication system according to various embodiments of the present disclosure. FIG. 16 is a flowchart illustrating a method of revising an IC layout design according to various embodiments of the present disclosure.

Referring now to FIGS. 1A and 1B, a three-dimensional perspective view and a top view of a portion of an Integrated Circuit (IC) device 90 are illustrated, respectively. The IC device 90 may be an intermediate device fabricated during processing of an IC, or a portion thereof, that may comprise static random-access memory (SRAM) and/or other logic circuits, passive components such as resistors, capacitors, and inductors, and active components such as p-type FETs (PFETs), n-type FETs (NFETs), FinFETs, metal-oxide semiconductor field effect transistors (MOSFET), complementary metal-oxide semiconductor (CMOS) transistors, bipolar transistors, high voltage transistors, high frequency transistors, and/or other memory cells. The present disclosure is not limited to any particular number of devices or device regions, or to any particular device configurations, unless otherwise claimed. For example, although the IC device 90 as illustrated is a three-dimensional FinFET device, the concepts of the present disclosure may also apply to planar FET devices or GAA devices.

Referring to FIG. 1A, the IC device 90 includes a substrate 110. The substrate 110 may comprise an elementary (single element) semiconductor, such as silicon, germanium, and/or other suitable materials; a compound semiconductor, such as silicon carbide, gallium arsenic, gallium phosphide, indium phosphide, indium arsenide, indium antimonide, and/or other suitable materials; an alloy semiconductor such as SiGe, GaAsP, AlInAs, AlGaAs, GaInAs, GaInP, GaInAsP, and/or other suitable materials. The substrate 110 may be a single-layer material having a uniform composition. Alternatively, the substrate 110 may include multiple material layers having similar or different compositions suitable for IC device manufacturing. In one example, the substrate 110 may be a silicon-on-insulator (SOI) substrate having a semiconductor silicon layer formed on a silicon oxide layer. In another example, the substrate 110 may include a conductive layer, a semiconductor layer, a dielectric layer, other layers, or combinations thereof. Various doped regions, such as source/drain regions, may be formed in or on the substrate 110. The doped regions may be doped with n-type dopants, such as phosphorus or arsenic, and/or p-type dopants, such as boron, depending on design requirements. The doped regions may be formed directly on the substrate 110, in a p-well structure, in an n-well structure, in a dual-well structure, or using a raised structure. Doped regions may be formed by implantation of dopant atoms, in-situ doped epitaxial growth, and/or other suitable techniques.

Three-dimensional active regions 120 are formed on the substrate 110. The active regions 120 are elongated fin-like structures that protrude upwardly out of the substrate 110. As such, the active regions 120 may be interchangeably referred to as fin structures 120 hereinafter. The fin structures 120 may be fabricated using suitable processes including photolithography and etch processes. The photolithography process may include forming a photoresist layer overlying the substrate 110, exposing the photoresist to a pattern, performing post-exposure bake processes, and developing the photoresist to form a masking element (not shown) including the resist. The masking element is then used for etching recesses into the substrate 110, leaving the fin structures 120 on the substrate 110. The etching process may include dry etching, wet etching, reactive ion etching (RIE), and/or other suitable processes. In some embodiments, the fin structure 120 may be formed by double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. As an example, a layer may be formed over a substrate and patterned using a photolithography process. Spacers are formed alongside the patterned layer using a self-aligned process. The layer is then removed, and the remaining spacers, or mandrels, may then be used to pattern the fin structures 120.

The IC device 90 also includes source/drain features 122 formed over the fin structures 120. The source/drain features 122 may include epi-layers that are epitaxially grown on the fin structures 120. The IC device 90 further includes isolation structures 130 formed over the substrate 110. The isolation structures 130 electrically separate various components of the IC device 90. The isolation structures 130 may include silicon oxide, silicon nitride, silicon oxynitride, fluoride-doped silicate glass (FSG), a low-k dielectric material, and/or other suitable materials. In some embodiments, the isolation structures 130 may include shallow trench isolation (STI) features. In one embodiment, the isolation structures 130 are formed by etching trenches in the substrate 110 during the formation of the fin structures 120. The trenches may then be filled with an isolating material described above, followed by a chemical mechanical planarization (CMP) process. Other isolation structure such as field oxide, local oxidation of silicon (LOCOS), and/or other suitable structures may also be implemented as the isolation structures 130. Alternatively, the isolation structures 130 may include a multi-layer structure, for example, having one or more thermal oxide liner layers.

The IC device 90 also includes gate structures 140 formed over and engaging the fin structures 120 on three sides in a channel region of each fin 120. The gate structures 140 may be dummy gate structures (e.g., containing an oxide gate dielectric and a polysilicon gate electrode), or they may be HKMG structures that contain a high-k gate dielectric and a metal gate electrode, where the HKMG structures are formed by replacing the dummy gate structures. Though not depicted herein, the gate structure 140 may include additional material layers, such as an interfacial layer over the fin structures 120, a capping layer, other suitable layers, or combinations thereof.

Referring to FIG. 1B, multiple fin structures 120 are oriented lengthwise along the X-direction, and multiple gate structures 140 are oriented lengthwise along the Y-direction, i.e., generally perpendicular to the fin structures 120. In many embodiments, the IC device 90 includes additional features such as gate spacers disposed along sidewalls of the gate structures 140, hard mask layer(s) disposed over the gate structures 140, and numerous other features.

It is also understood that the various aspects of the present disclosure discussed below may apply to multi-channel devices such as Gate-All-Around (GAA) devices. FIG. 1C illustrates a three-dimensional perspective view of an example GAA device 150. For reasons of consistency and clarity, similar components in FIG. 1C and FIGS. 1A-1B will be labeled the same. For example, active regions such as fin structures 120 rise vertically upwards out of the substrate 110 in the Z-direction. The isolation structures 130 provide electrical separation between the fin structures 120. The gate structure 140 is located over the fin structures 120 and over the isolation structures 130. A mask 155 is located over the gate structure 140, and gate spacers 160 are located on sidewalls of the gate structure 140. A capping layer 165 is formed over the fin structures 120 to protect the fin structures 120 from oxidation during the forming of the isolation structures 130.

A plurality of nano-structures 170 is disposed over each of the fin structures 120. The nano-structures 170 may include nano-sheets, nano-tubes, or nano-wires, or some other type of nano-structure that extends horizontally in the X-direction. Portions of the nano-structures 170 under the gate structure 140 may serve as the channels of the GAA device 150. Dielectric inner spacers 175 may be disposed between the nano-structures 170. In addition, although not illustrated for reasons of simplicity, each of the nano-structures 170 may be wrapped around circumferentially by a gate dielectric as well as a gate electrode. In the illustrated embodiment, the portions of the nano-structures 170 outside the gate structure 140 may serve as the source/drain features of the GAA device 150. However, in some embodiments, continuous source/drain features may be epitaxially grown over portions of the fin structures 120 outside of the gate structure 140. Regardless, conductive source/drain contacts 180 may be formed over the source/drain features to provide electrical connectivity thereto. An interlayer dielectric (ILD) 185 is formed over the isolation structures 130 and around the gate structure 140 and the source/drain contacts 180.

FIG. 2 illustrates an example type of a memory device in which transistors such as planar transistors, FinFET transistors, or gate-all-around (GAA) transistors may be implemented. In that regard, FIG. 2 illustrates the circuit schematic of an example Static Random-Access Memory (SRAM) device, for example, as a single-port SRAM cell (e.g., 1-bit SRAM cell) 200. The single-port SRAM cell 200 includes pull-up transistors PU1, PU2; pull-down transistors PD1, PD2; and pass-gate transistors PG1, PG2. As show in the circuit diagram, transistors PU1 and PU2 are p-type transistors, and transistors PG1, PG2, PD1, and PD2 are n-type transistors. According to the various aspects of the present disclosure, the PG1, PG2, PD1, and PD2 transistors are implemented with thinner spacers than the PU1 and PU2 transistors. Since the SRAM cell 200 includes six transistors in the illustrated embodiment, it may also be referred to as a 6T SRAM cell. Regardless, transistors such as the FinFET or GAA transistors may be used to implement the PG1, PG2, PD1, PD2, PU1, and/or the PU2 transistors.

The drains of pull-up transistor PU1 and pull-down transistor PD1 are coupled together, and the drains of pull-up transistor PU2 and pull-down transistor PD2 are coupled together. Transistors PU1 and PD1 are cross-coupled with transistors PU2 and PD2 to form a first data latch. The gates of transistors PU2 and PD2 are coupled together and to the drains of transistors PU1 and PD1 to form a first storage node SN1, and the gates of transistors PU1 and PD1 are coupled together and to the drains of transistors PU2 and PD2 to form a complementary first storage node SNB1. Sources of the pull-up transistors PU1 and PU2 are coupled to power voltage Vcc (also referred to as Vdd), and the sources of the pull-down transistors PD1 and PD2 are coupled to a voltage Vss, which may be an electrical ground in some embodiments.

The first storage node SN1 of the first data latch is coupled to bit line BL through pass-gate transistor PG1, and the complementary first storage node SNB1 is coupled to complementary bit line BLB through pass-gate transistor PG2. The first storage node SN1 and the complementary first storage node SNB1 are complementary nodes that are often at opposite logic levels (logic high or logic low). Gates of pass-gate transistors PG1 and PG2 are coupled to a word line WL. SRAM devices such as the SRAM cell 200 may be implemented using “planar” transistor devices, with FinFET devices, and/or with GAA devices.

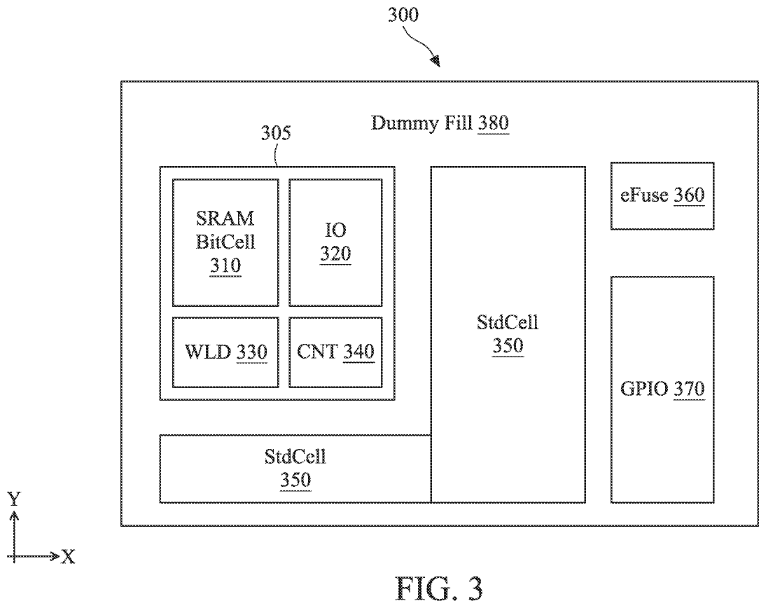

FIG. 3 is a block diagram of a portion of an electronic memory device 300 in which the SRAM cell 200 may be implemented. The electronic memory device 300 may include an SRAM region 305. The SRAM region 305 includes a SRAM BitCell region 310. The SRAM BitCell region 310 is the portion of the SRAM region 305 where a plurality of SRAM devices (e.g., the SRAM cell 200 of FIG. 1) are implemented. For example, the plurality of SRAM devices may be implemented as an SRAM array in the SRAM BitCell region 310. In some embodiments, the SRAM devices in the SRAM BitCell region 310 are implemented using the FinFET transistors and/or the GAA transistors discussed above, where the active regions of these transistors have substantially uniform widths. For example, if the active regions each extend in an elongated manner in an X-direction in the top view, then their widths measured in a Y-direction (perpendicular to the X-direction) are substantially uniform. In other words, the width of each active region in the SRAM BitCell region 310 may be free of jogs or other artificial enlargements. The substantial uniform width of the active regions in the SRAM BitCell region 310 may not be the case for the other circuits of the electronic memory device 300, as discussed later in more detail in accordance with various aspects of the present disclosure.

The SRAM region 305 may also include various periphery non-memory cell circuit regions that surround the SRAM BitCell region 310, such as an IO (input/output) region 320, a WLD (word line driver) region 330, and a CNT (control circuit) region 340. In some embodiments, the IO region 320 contains electrical circuitry that handles the input/output for the SRAM devices of the SRAM BitCell region 310, the WLD region 330 contains electrical circuitry that drives the word line for the SRAM devices of the SRAM BitCell region 310, and the CNT region 340 contains electrical circuitry that controls the electrical operation of the SRAM devices of the SRAM BitCell region 310. The IO region 320, the WLD region 330, and the CNT region 340 may be collectively referred to as periphery regions. In some embodiments, the transistors of the IO region 320, the WLD region 330, and the CNT region 340 are also implemented using the FinFET transistors and/or the GAA transistors discussed above, but the active regions of these transistors may have substantially non-uniform widths. For example, if the active regions each extend in an elongated manner in the X-direction in the top view, then their widths measured in the Y-direction may contain jogs or artificial enlargements. In this manner, certain transistors may have larger active regions than other transistors, where the transistors with the larger active regions are configured to achieve faster speeds, while the transistors with the smaller active regions are configured to achieve lower leakage, as discussed later in more detail in accordance with various aspects of the present disclosure.

The electronic memory device 300 may further includes a StdCell (standard cell) region 350, an eFuse region 360, and a GPIO (general-purpose input/output) region 370. In some embodiments, the StdCell region 350 may include logic circuits for performing Boolean logic operations, the eFuse region 360 may include microscopic electronic fuses that are configured to enable dynamic real-time reprogramming of chips, and the GPIO region 370 is configured to handle the input/output between the electronic memory device 300 and the devices external to the electronic memory device 300. A dummy fill region 380 may be implemented in the electronic memory device 300 between these regions 350-370, as well as between these regions 350-370 and the SRAM region 305. In some embodiments, the transistors of the StdCell region 350, the eFuse region 360, and the GPIO region 370 are also implemented using the FinFET transistors and/or the GAA transistors discussed above. In some embodiments, the active regions of the transistors in the StdCell region 350 and the GPIO region 370 may also have substantially non-uniform widths, for example, containing jogs or artificial enlargements. As discussed above, this helps to achieve faster speeds for transistors (with enlarged active regions) where speed is a more import concern, and reduced leakage for transistors (with diminished active regions) where leakage is a more important concern.

The non-uniformity of the active regions in certain circuits of the electronic memory device 300 is illustrated in more detail in FIGS. 4-11, which are simplified diagrammatic top views of portions of the electronic memory device 300. For reasons of consistency and clarity, similar components appearing in FIG. 3 and FIGS. 4-11 will be labeled the same.

Referring now to FIG. 4, the top views of an example embodiment of the SRAM region 305 and some of its components are illustrated in more detail. In this example embodiment, the SRAM region 305 contains two SRAM BitCell regions 310 (e.g., containing SRAM cell arrays) and two IO regions 320. The WLD region 330 and the CNT region 340 are disposed between the two SRAM BitCell regions 310 and between the two IO regions 320. It is understood that the layout and/or configuration between the two SRAM BitCell regions 310 may be substantially identical to each other, and the layout and/or configuration between the two IO regions 320 may be substantially identical to each other as well. The IO regions 320, the WLD region 330, and the CNT region 340 may be referred to as periphery circuit regions.

FIG. 4 also illustrates a portion 320A of the IO region 320. The portion 320A may span horizontally in the X-direction in the top view, and it may include a N-region, a P-region, and another N-region. The P-region is located between the two N-regions in the Y-direction. A sub-portion 320A-1 of the portion 320A is also illustrated in more detail. For example, the sub-portion 320A-1 is located in one of the N-regions, and it includes an active region 410 that also extends in an elongated manner in the X-direction horizontally. The active region 410 may include the vertically protruding fin structures of the FinFET or GAA devices discussed above in association with FIGS. 1A-1C.

One of the unique aspects of the present disclosure is that the active region 410 has artificial enlargements and/or reductions in certain areas. For example, the active region 410 of the sub-portion 320A-1 has a segment 410A and a segment 410B that are disposed directly adjacent to each other, and they each extend in the X-direction horizontally. However, the segment 410A has a dimension 420A (also referred to as a width) measured in the Y-direction, and the segment 410B has a dimension 420B measured in the Y-direction, where the dimension 420A is greater than the dimension 420B. In other words, the segment 410A is enlarged compared to the segment 410B. In some embodiments, the dimension 420A is in a range between about 30 nanometers (nm) and about 39 nm, and the dimension 420B is in a range between about 20 nm and about 29 nm. Such an enlargement of the segment 410A may also be manifested by a jog 430 between the segment 410A and 410B. The jog 430 may correspond to a protrusion of an edge of the segment 410A beyond an edge of the segment 410B, while the edges of the segments 410A-410B on the opposite side are substantially flush with one another. In some embodiments, the jog 430 may be in a range between about 8 nm and about 12 nm.

According to the various aspects of the present disclosure, the enlargement of the segment 410A is artificially made (e.g., by revising an original IC layout design of the SRAM region 305) to achieve certain device performance enhancements. For example, a larger active region results in faster transistor speed. Since the IO region 320 may contain various types of circuits that have different transistor speeds, it is desirable to optimize the device performance by enlarging the portions of the active region 410 that correspond to the transistors needing faster speeds (e.g., transistors that are electrically coupled to the bit-lines of the SRAM cells). Stated differently, the present disclosure may determine, based on the original IC layout design of the electronic memory device 205, which portions of the IO region 320 include circuits that need faster transistor speed, and which portions of the IO region 320 do not include circuits that need faster transistor speed. Based on such a determination, the present disclosure may revise the IC layout design by artificially enlarging segments of the active region (e.g., the segment 410A) that correspond to the circuits with faster speed. The size of the rest of the active region 410 may be kept the same (e.g., having the same dimension 420B as before the IC layout design revision). Alternatively, the segment 410B may correspond to portions of the IO region 320 where speed is not an important concern, but leakage is. Since a smaller active region may result in a lower leakage, the segment 410B may correspond to circuits of the IO region 320 where a reduced leakage is desired. In other words, the segment 410B may have been shrunk in the Y-direction to achieve a smaller dimension 420B in the Y-direction (e.g., the dimension 420B is smaller than the corresponding dimension in the original IC layout design). In this manner, the same active region 410 of the IO region may be configured differently based on the different needs and/or considerations of their corresponding circuits.

It is understood that although the discussions above regarding resizing the active region 410 utilizes the IO region specifically as an example, it is not intended to be limiting to the IO region 320 unless otherwise claimed. In other embodiments, such a resizing of the active region 410 may apply to the WLD region 330 and/or the CNT region 340 of the SRAM region 305 as well, or even the GPIO region 370. This is because these other regions of the electronic memory device 300 may also include some circuits where transistor speed is a more important concern (and therefore an enlarged active region width may be more beneficial), as well as some other circuits where reduced leakage is a more important concern (and therefore a shrunken active region width may be more beneficial).

In comparison to the regions 320-340 of the SRAM region 305, the SRAM BitCell region 310 itself may have active regions with substantially uniform thicknesses. For example, a portion of the SRAM BitCell region 310 is illustrated in more detail in FIG. 4. The portion 310A may span horizontally in the X-direction in the top view, and it may include a plurality of active regions 440 (two examples of which are illustrated in FIG. 4) that also each extends in an elongated manner in the X-direction horizontally. The active regions 440 may include the vertically protruding fin structures of the FinFET or GAA devices discussed above in association with FIGS. 1A-1C. However, unlike the active region 410 of the IO region 320 discussed above, the active regions 440 of the SRAM BitCell region 310 may each have a substantially uniform dimension 450 in the Y-direction. In other words, although each of the active regions 440 may experience slight variations in its Y-direction dimension throughout, such variations may be due to manufacturing imperfections, as opposed to intentional design.

There is not a significant impetus to resize the active regions of the SRAM BitCell region 310, because the SRAM BitCell region 310 may not include different circuits with different considerations (e.g., faster speed versus lower leakage, etc.). As such, although the active regions of the electronic memory device 300 may all be fabricated on the same wafer using similar fabrication processes, some regions (e.g., the IO region 320, the WLD region 330, or the CNT region 340) of the electronic memory device 300 may have differing active region sizes (e.g., widths in the Y-direction), while other regions (e.g., the SRAM BitCell region 310) may have active regions with more uniformly sizes.

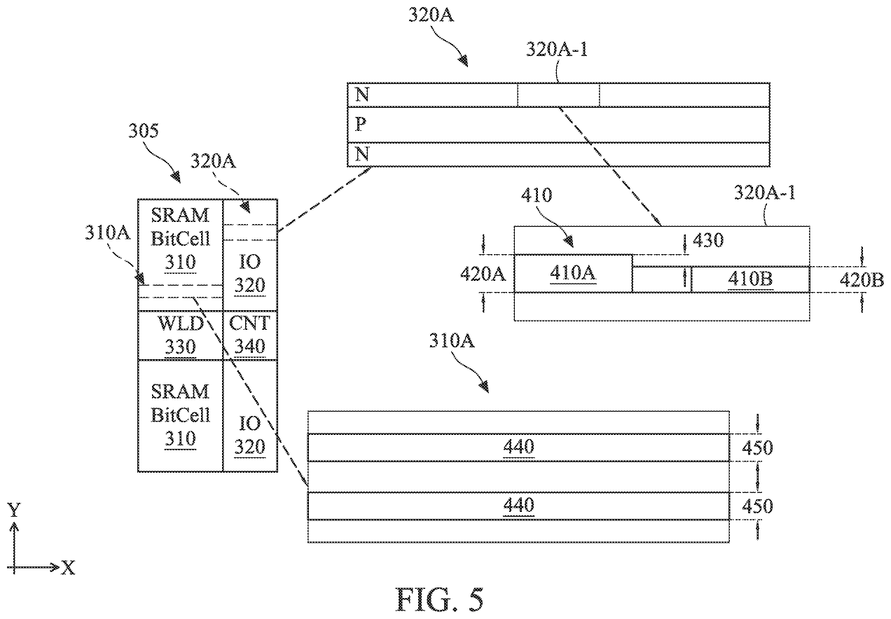

FIG. 5 illustrates another embodiment of resizing the active regions for certain components of the electronic memory device 300, such as for the IO region 320, the WLD region 330, and the CNT region 340 of the SRAM region 305. For reasons of consistency and clarity, similar components appearing in FIGS. 4-5 will be labeled the same, and the discussions above with respect to these components in the embodiment of FIG. 4 will also apply to the embodiment of FIG. 5.

Similar to the embodiment of FIG. 4, the active region 410 of the IO region 320 is also resized to have a wider segment 410A and a narrower segment 410B in the embodiment of FIG. 5. For example, the segment 410A has the dimension 420A that is larger than the dimension 420B of the segment 410B in the Y-direction. This results in the jog 430 between the segments 410A and 410B. However, whereas the jog is disposed “below” the 410B in the Y-direction in the embodiment of FIG. 4, the jog is disposed “above” the 410B in the Y-direction in the embodiment of FIG. 5.

Regardless of the relative location of the jog 430, however, the embodiment of FIG. 5 still allows flexible configuration of the active region 410 based on the design and/or operational objective. For example, the segment 410A of the active region 410 is configured to be larger, because faster speed is more important for the transistors corresponding to the segment 410A. In comparison, the segment 410B of the active region 410 is configured to be smaller, because reduced leakage is more important for the transistors corresponding to the segment 410B. Meanwhile, the active regions 440 in the SRAM BitCell region 310 still maintains a relatively uniform dimension 450 (e.g., width measured in the Y-direction) throughout.

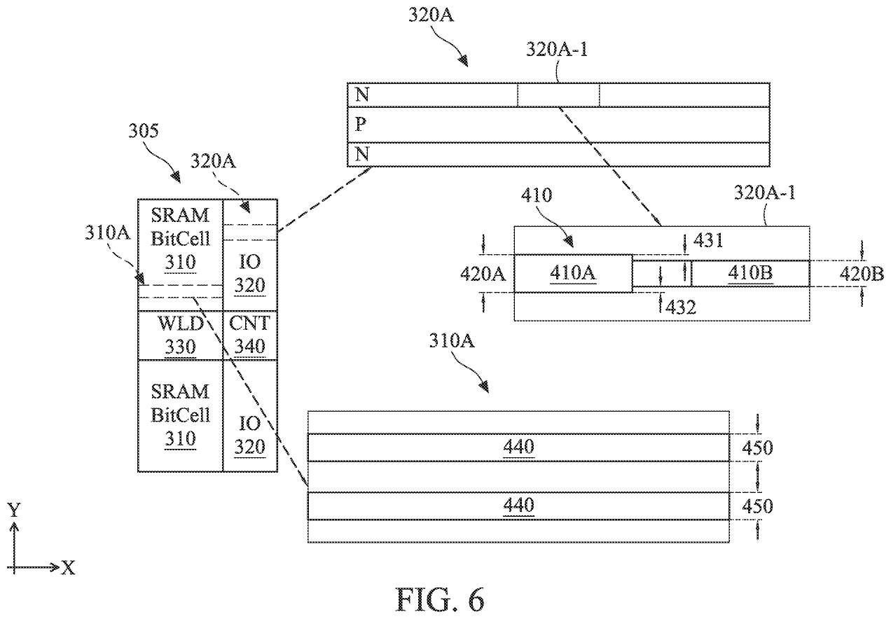

FIG. 6 illustrates yet another embodiment of resizing the active regions for certain components of the electronic memory device 300, such as for the IO region 320, the WLD region 330, and the CNT region 340 of the SRAM region 305. Again, for reasons of consistency and clarity, similar components appearing in FIGS. 4-6 will be labeled the same, and the discussions above with respect to these components in the embodiments of FIGS. 4-5 will also apply to the embodiment of FIG. 6.

Similar to the embodiments of FIGS. 4-5, the active region 410 of the IO region 320 is also resized to have a wider segment 410A and a narrower segment 410B in the embodiment of FIG. 6. For example, the segment 410A has the dimension 420A that is larger than the dimension 420B of the segment 410B in the Y-direction. However, whereas the embodiments of FIGS. 4-5 each have a jog 430 in one direction, the embodiment of FIG. 6 has two jogs 431 and 432 in opposite directions. For example, the jog 431 exists between the segment 410A and the segment 410B and is “above” the segment 410B in the Y-direction, while the jog 432 exists between the segment 410A and the segment 410B and is “below” the segment 410B in the Y-direction. In some embodiments, the jogs 431 and 432 may be smaller than the jog 430 of FIG. 4 or FIG. 5. For example, whereas the jog 430 may be in a range between about 8 nm and about 12 nm, the jogs 431-432 may each be in a range between about 3 nm and about 7 nm in some embodiments. It is also understood that the jogs 431 and 432 may be substantially equal to one another in some embodiments, or they may be different from one another in other embodiments.

Regardless of the relative locations and/or the number of the jogs 431-432, however, the embodiment of FIG. 6 still allows a flexible configuration of the active region 410 based on the design and/or operational objective. For example, the segment 410A of the active region 410 is configured to be larger, because faster speed is more important for the transistors corresponding to the segment 410A. In comparison, the segment 410B of the active region 410 is configured to be smaller, because reduced leakage is more important for the transistors corresponding to the segment 410B. Meanwhile, the active regions 440 in the SRAM BitCell region 310 still maintains a relatively uniform dimension 450 (e.g., width measured in the Y-direction) throughout.

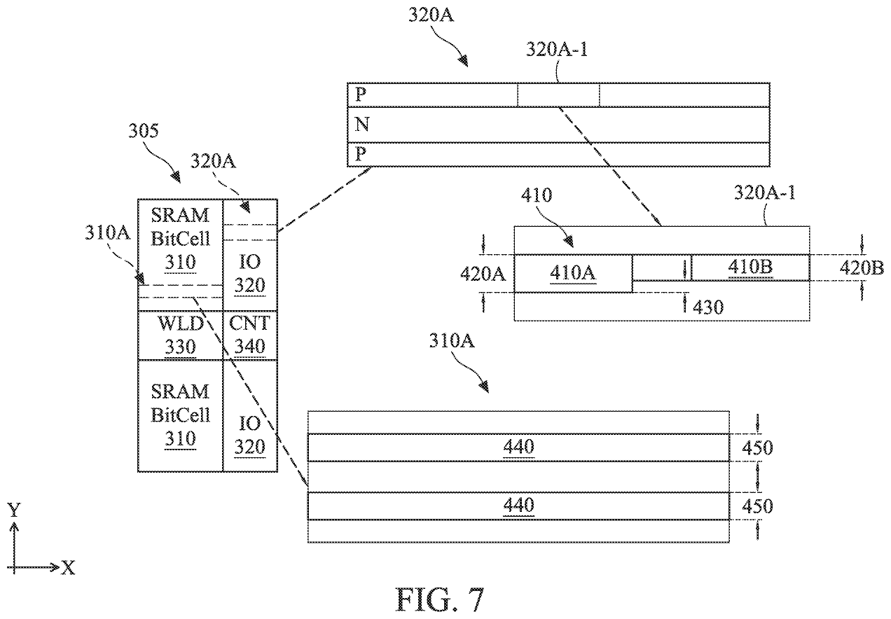

FIG. 7 illustrates yet another embodiment of resizing the active regions for certain components of the electronic memory device 300, such as for the IO region 320, the WLD region 330, and the CNT region 340 of the SRAM region 305. Again, for reasons of consistency and clarity, similar components appearing in FIGS. 4-7 will be labeled the same, and the discussions above with respect to these components in the embodiments of FIGS. 4-6 will also apply to the embodiment of FIG. 7.

Similar to the embodiments of FIGS. 4-6, the active region 410 of the IO region 320 is also resized to have a wider segment 410A and a narrower segment 410B in the embodiment of FIG. 7. For example, the segment 410A has the dimension 420A that is larger than the dimension 420B of the segment 410B in the Y-direction. However, whereas the embodiments of FIGS. 4-6 shows the active region 410 being implemented in an N-region in the portion 320A of the IO region having an N-P-N configuration, the embodiment of FIG. 7 implements the active region 410 in a P-region in the portion 320A of the IO region having a P-N-P configuration. Furthermore, it is understood that the resizing of the active region 410 in the P-N-P configuration may also apply to the embodiments of FIG. 6 and FIG. 7. In addition, it is understood that the resizing of the active region 410 may be applied to either the P-region alone, or to the N-region alone, or simultaneously applied to both the N-region and the P-region, regardless of whether the P-N-P configuration or the N-P-N configuration is implemented. Meanwhile, the active regions 440 of the SRAM BitCell region 310 may still maintain their relatively uniform dimensions 450 in the Y-direction.

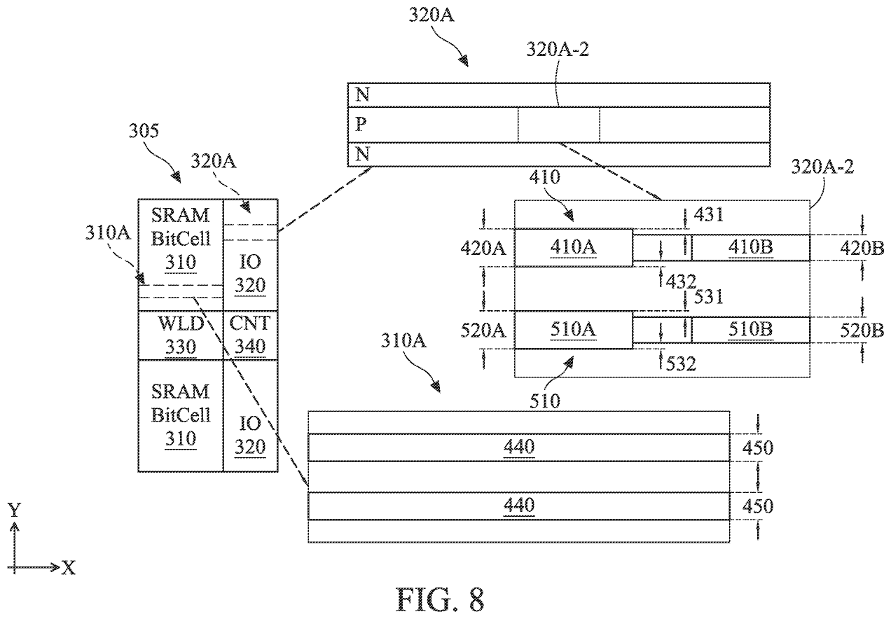

FIG. 8 illustrates yet another embodiment of resizing the active regions for certain components of the electronic memory device 300, such as for the IO region 320, the WLD region 330, and the CNT region 340 of the SRAM region 305. Again, for reasons of consistency and clarity, similar components appearing in FIGS. 4-8 will be labeled the same, and the discussions above with respect to these components in the embodiments of FIGS. 4-7 will also apply to the embodiment of FIG. 8.

Similar to the embodiments of FIGS. 4-7, the active regions of the IO region 320 are resized to have wider and narrower segments depending on the needs of their respective circuitries. For example, a portion 320A-2 of the IO region 320 is located in the P-region, which may be wider than the N-regions in the Y-direction. Two example active regions 410 and 510 are illustrated in the portion 320A-2 of the IO region 320 of FIG. 8. For the active region 410, its resizing is similar to that of the embodiment discussed above with reference to FIG. 6. For example, the active region 410 is resized to have the wider segment 410A having two jogs 431 and 432 with respect to the narrower segment 410B on opposite sides in the Y-direction. In addition, the active region 510 is resized in a similar manner, such that it has a wider segment 510A connected to the narrower segment 510B, where the segments 510A and 510B have dimensions 520A and 520B, respectively. In some embodiments, the values of the dimensions 520A and 520B are substantially equal to the values of the dimensions 420A and 420B, respectively. The active region 510 also contains jogs 531 and 532 on opposite sides of the narrower segment 510B. In some embodiments, the values of the jogs 531 and 532 are substantially equal to the values of the jogs 431 and 432, respectively. As discussed above, the wider segments 410A and 510A may be used to implement transistors for which a faster speed is a more important concern, whereas the narrower segments 410B and 510B may be used to implement transistors for which a reduced leakage is a more important concern. Meanwhile, the active regions 440 of the SRAM BitCell region 310 may still maintain their relatively uniform dimensions 450 in the Y-direction.

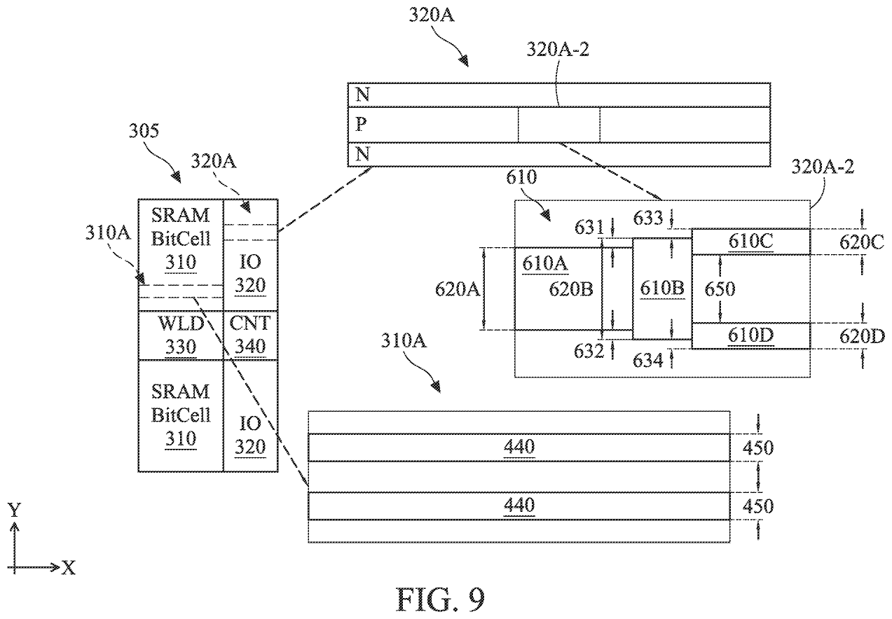

FIG. 9 illustrates yet another embodiment of resizing the active regions for certain components of the electronic memory device 300, such as for the IO region 320, the WLD region 330, and the CNT region 340 of the SRAM region 305. Again, for reasons of consistency and clarity, similar components appearing in FIGS. 4-9 will be labeled the same, and the discussions above with respect to these components in the embodiments of FIGS. 4-8 will also apply to the embodiment of FIG. 9.

Similar to the embodiments of FIGS. 4-8, the active regions of the IO region 320 are resized to have wider and narrower segments depending on the needs of their respective circuitries. For example, the portion 320A-2 of the IO region 320 (which is located in the P-region in this embodiment) contains an active region 610. The active region 610 includes a segment 610A having a dimension 620A measured in the Y-direction, a segment 610B having a dimension 620B measured in the Y-direction, as well as two branch segments 610C and 610D having respective dimensions 620C and 620D measured in the Y-direction. As is clearly shown in FIG. 9, the segment 610B is wider than the segment 610A, meaning that the dimension 620B is greater than the dimension 620A. As a result, two jogs 631 and 632 are formed at an interface between the segment 610A and 610B, with the jog 631 being located “above” the segment 610A in the Y- direction, and the jog 632 being located “below” the segment 610A in the Y-direction. The jogs 631 and 632 may be substantially equal to one another or may differ from one another in value.

Meanwhile, the branch segments 610C and 610D split off from the segment 610B, with a distance 650 separating the branch segments 610C and 610D. The branch segments 610C and 610D have respective dimensions 620C and 620D measured in the Y-direction, where the dimensions 620C and 620D are each smaller than the dimension 620A. Jogs 633 and 634 also exist between the segment 610B and the branch segments 610C and 610D, respectively. In more detail, the jog 633 is located “above” the segment 610B in the Y-direction, and the jog 634 is located “below” the segment 610B in the Y-direction. The jogs 633 and 634 may be substantially equal to one another or may differ from one another in value. In some embodiments, the jogs 633 and 634 may each be smaller than each of the jogs 631 or 632.

In some embodiments, the dimension 620A is in a range between about 50 nm and about 70 nm, the dimension 620B is in a range between about 68 nm and about 88 nm, the dimension 620C is in a range between about 20 nm and about 29 nm, the dimension 620D is in a range between about 20 nm and about 29 nm, the jogs 631 and 632 are each is in a range between about 3 nm and about 7 nm, the jogs 633 and 634 are each in a range between about 1 nm and about 5 nm, and the distance 650 may be in a range between about 20 nm and about 40 nm.

Regardless of the specific values of the various dimensions listed above, it can be seen that the active region 610 of FIG. 9 is also configured to achieve independent size tuning. For example, the segment 610A is relatively wide in the Y-direction, and thus it can be used to implement transistors with relatively fast speeds. The segment 610B is even wider than the segment 610A in the Y-direction, and as such, the segment 610B can be used to implement transistors with even faster speeds. Meanwhile, the branch segments 610C and 610D are relatively narrow in the Y-direction, and thus it can be used to implement transistors with relatively low leakage. The above configuration also ensures that there is a relatively smooth transition from the segment 610A to the branch segments 610C and 610D, with the segment 610B serving as an intermediate or a transitionary segment in between. Accordingly, the jogs 631, 632, 633, and 634 may each be small, which is more process-friendly than if a relatively large jog had existed directly between the segment 610A and the branch segments 610C or 610D.

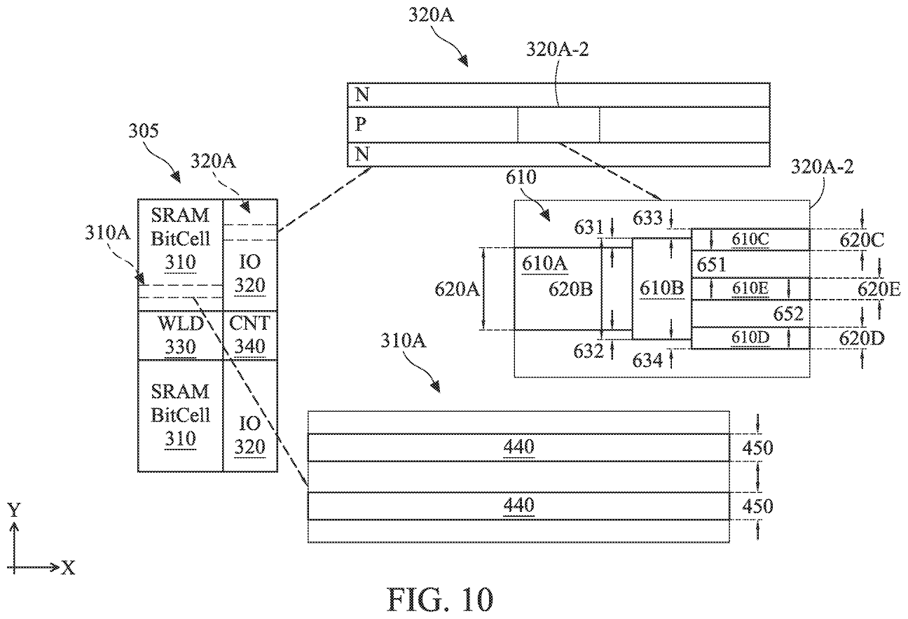

FIG. 10 illustrates yet another embodiment of resizing the active regions for certain components of the electronic memory device 300, such as for the IO region 320, the WLD region 330, and the CNT region 340 of the SRAM region 305. Again, for reasons of consistency and clarity, similar components appearing in FIGS. 4-10 will be labeled the same, and the discussions above with respect to these components in the embodiments of FIGS. 4-9 will also apply to the embodiment of FIG. 10.

The embodiment of FIG. 10 shares certain similarities with the embodiment of FIG. 9, in that the portion 320A-2 of the IO region 320 contains an active region with multiple segments having different widths, including branch segments 610C and 610D. However, the embodiment of FIG. 10 has three branch segments 610C, 610D, and 610E, compared to the two branch segments 610C and 610D of the embodiment of FIG. 9. The branches 610C and 610E are separated from one another by a distance 651, and the branches 610E and 610D are separated from one another by a distance 652. The jogs 631, 632, 633, and 634 may still exist in a manner similar to that discussed above with reference to FIG. 9. The configuration of the “extra” branch segment 610E in this embodiment provides even more flexibility with respect to the implementation of circuitries using transistors with reduced leakage.

It is understood that although the active region(s) in the embodiments of FIGS. 8-10 were implemented in the P-region in an N-P-N configuration, the same concepts may apply in an N-region in a P-N-P configuration as well. For example, the two active regions 410 and 510 of FIG. 8 may be implemented in an N-region in a P-N-P configuration. As another example, the active region 610 with a relatively wide segment 610A, two branch segments 610C/610D, and an intermediate segment 610B disposed between the segments 610A and 610C/610D may be implemented in an N-region in a P-N-P configuration. As a further example, the active region 610 with a relatively wide segment 610A, three branch segments 610C/610D/610E, and an intermediate segment 610B disposed between the segments 610A and 610C/610D/610E may be implemented in an N-region in a P-N-P configuration.

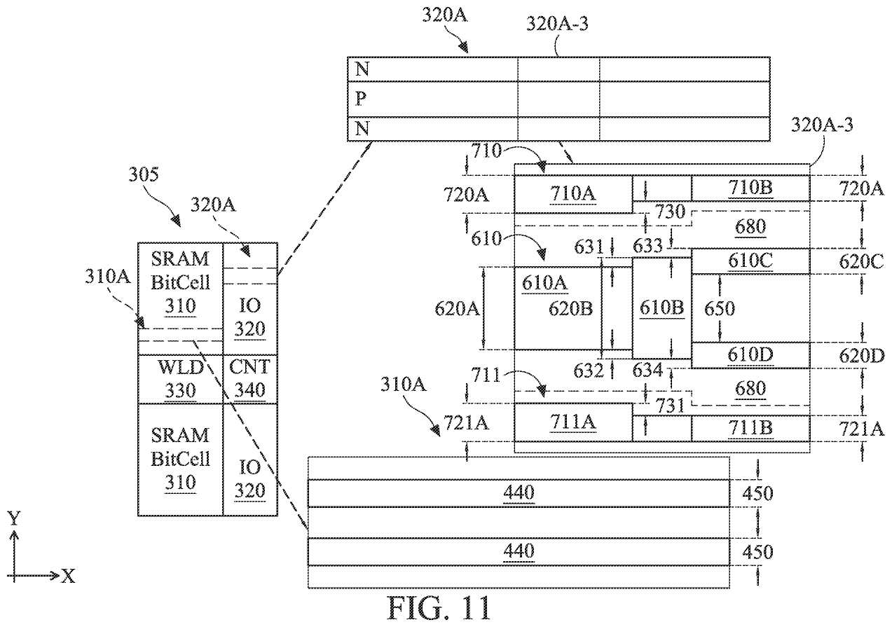

FIG. 11 illustrates yet another embodiment of resizing the active regions for certain components of the electronic memory device 300, such as for the IO region 320, the WLD region 330, and the CNT region 340 of the SRAM region 305. Again, for reasons of consistency and clarity, similar components appearing in FIGS. 4-11 will be labeled the same, and the discussions above with respect to these components in the embodiments of FIGS. 4-10 will also apply to the embodiment of FIG. 11.

The embodiment of FIG. 11 may share similarities with the embodiment of FIGS. 4-5 and FIG. 9. For example, an active region 710 is implemented in one of the N-regions, and another active region 711 is implemented in the other one of the N-regions. The active region 710 is configured in a similar manner as the active region 410 of FIG. 4, and the active region 711 is configured in a similar manner as the active region 410 of FIG. 5. For example, similar to the active region 410 in FIG. 4, the active region 710 includes a wider segment 710A having a dimension 720A and a narrower segment 710B having a dimension 720B, where the dimension 720A is greater than the dimension 720B, which creates a jog 730 between the segment 710A and the segment 710B. Meanwhile, similar to the active region 410 in FIG. 5, the active region 711 includes a wider segment 711A having a dimension 721A and a narrower segment 711B having a dimension 721B, where the dimension 721A is greater than the dimension 721B, which creates a jog 731 between the segment 711A and the segment 711B.

The embodiment of FIG. 11 also implements the active region 610 in a manner substantially similar to how the active region 610 was implemented in the embodiment of FIG. 9. For example, the active region 610 is located in the P-region, and it includes the segment 610A, the two branch segments 610C-610D, and the intermediate segment 610B (which is wider than the segment 610A). Note that a doped well 680 (e.g., an N-well) is also illustrated, which surrounds the active region 610 in the top view of FIG. 11. It is understood that the active region 610 may be formed vertically in a Z-direction (orthogonal to a plane defined by the X-direction and the Y-direction) over the N-well, such as in FIG. 1A or FIG. 1C. Meanwhile, the active regions 440 of the SRAM BitCell region 310 still maintain substantially uniform dimensions 450.

It is understood that although FIG. 11 is implemented using an N-P-N configuration, the concepts discussed above may apply to a P-N-P configuration as well. For example, the active regions 710 and 711 may be implemented in the two P-regions on opposite sides of the N-region, and the active region 610 may be implemented in the N-region. In any case, FIG. 11 shows that the configuration of the active regions herein may be flexible, and different portions of the periphery circuits may be configured differently to suit their particular design and/or manufacturing needs.

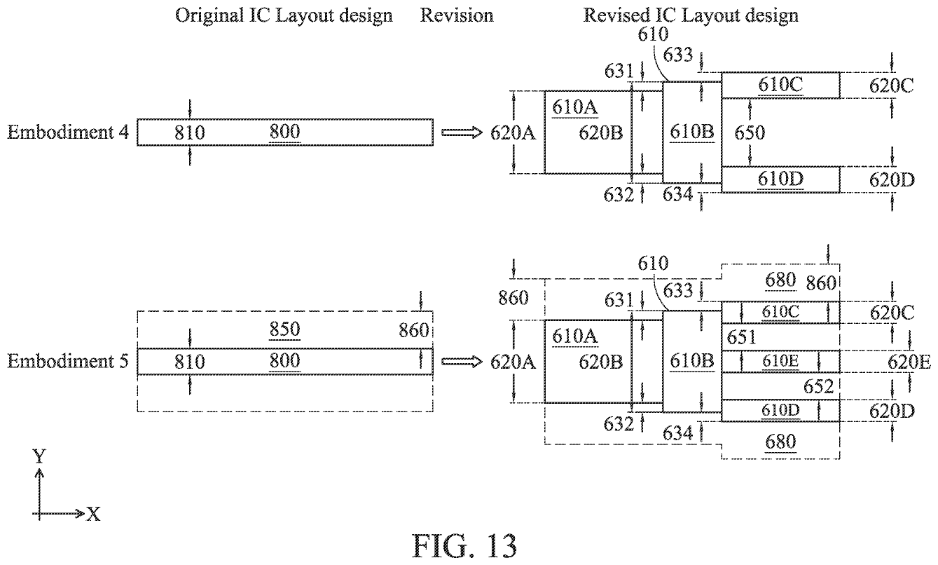

FIGS. 12-13 illustrate the revision of an original IC layout design to generate a revised (e.g., new) IC layout design according to various embodiments of the present disclosure. In these embodiments, the original IC layout design may include an active region 800 that is located in a periphery circuit, such as in the IO region 320, in the WLD region 330, in the CNT region 340, or even in the GPIO region 370 discussed above with reference to FIG. 3. In some embodiments, the original IC layout design may be in the format of a Graphic Data System (GDS) file, which includes solder masks, geometry, layers, component labels, and the general layout of a circuit. The GDS file may have a binary format in some embodiments. The original IC layout design may be generated by an IC design house, which may then send the original IC layout design to a fabrication facility (e.g., an IC foundry). The fabrication facility may revise the original IC layout design to generate a revised IC layout design. Again, for reasons of consistency and clarity, similar components appearing in FIGS. 12-13 will be labeled the same as they were in FIGS. 1-11.

Referring now to FIG. 12, an embodiment 1, an embodiment 2, and an embodiment 3 of the IC layout revision process are illustrated. In each of the embodiments 1, 2, and 3, the active region 800 in the original IC layout design extends in the X-direction and has a dimension (e.g., a width) 810 measured in the Y-direction. According to the original IC layout design in embodiments 1-3, the active region 800 may assume the shape of a rectangle, where the dimension 810 is uniform throughout the length of the active region 800 in the X-direction. However, in embodiment 1, the active region 800 may be transformed into an active region 410 (similar to the embodiment of FIG. 4) in the revised IC layout design, where the active region 410 includes a wider segment 410A having a dimension 420A and a narrower segment 410B having a dimension 420B in the Y-direction, where the dimension 420A is greater than the dimension 420B. In some embodiments, the dimension 420A is greater than the dimension 810, while the dimension 420B is smaller than the dimension 810. In other embodiments, the dimension 420A is greater than the dimension 810, while the dimension 420B is approximately equal to the dimension 810. A jog 430 is also created due to the size discrepancy between the segments 410A and 410B. It is understood that when an IC wafer is fabricated using the revised IC layout design of embodiment 1, the resulting active region may appear substantially similar to the active region 410 of FIG. 4 discussed above.

In embodiment 2, the active region 800 may also be transformed into an active region 410 (similar to the embodiment of FIG. 5) in the revised IC layout design, where the active region 410 includes a wider segment 410A having a dimension 420A and a narrower segment 410B having a dimension 420B in the Y-direction, where the dimension 420A is greater than the dimension 420B. In some embodiments, the dimension 420A is greater than the dimension 810, while the dimension 420B is smaller than the dimension 810. In other embodiments, the dimension 420A is greater than the dimension 810, while the dimension 420B is approximately equal to the dimension 810. A jog 430 is also created due to the size discrepancy between the segments 410A and 410B. One difference between embodiments 1 and 2 is the relative location of the jogs 430. In embodiment 1, the jog 430 is located “below” the segment 410B in the Y-direction, whereas the jog 430 is located “above” the segment 410B in the Y-direction. It is understood that when an IC wafer is fabricated using the revised IC layout design of embodiment 2, the resulting active region may appear substantially similar to the active region 410 of FIG. 5 discussed above.

In embodiment 3, the active region 800 may also be transformed into an active region 410 (similar to the embodiment of FIG. 5) in the revised IC layout design, where the active region 410 includes a wider segment 410A having a dimension 420A and a narrower segment 410B having a dimension 420B in the Y-direction, where the dimension 420A is greater than the dimension 420B. In some embodiments, the dimension 420A is greater than the dimension 810, while the dimension 420B is smaller than the dimension 810. In other embodiments, the dimension 420A is greater than the dimension 810, while the dimension 420B is approximately equal to the dimension 810. However, whereas the active region 410 in embodiments 1 and 2 each have a singular jog 430, the active region 410 in embodiment 3 has two jogs 431 and 432, with the jog 431 located “above” the segment 410B in the Y-direction, and the jog 432 is located “below” the segment 410B in the Y-direction. A jog 430 is also created due to the size difference between the segments 410A and 410B.

One difference between embodiments 1 and 2 is the relative location of the jogs 430. In embodiment 1, the jog 430 is located “below” the segment 410B in the Y-direction, whereas the jog 430 is located “above” the segment 410B in the Y-direction. In other words, the embodiments 1 and 2 each have flush edges between the segments 410A and 410B on one side, and the jog 430 is located on the opposite side of the flush edges, but embodiment 3 has no flush edges between the segments 410A and 410B, thereby resulting in the two jogs 431 and 432. It is understood that when an IC wafer is fabricated using the revised IC layout design of embodiment 3, the resulting active region may appear substantially similar to the active region 410 of FIG. 6 discussed above.

Referring now to FIG. 13, an embodiment 4 and an embodiment 5 of the IC layout revision process are illustrated. Again, the active region 800 with the uniform dimension 810 in the original IC layout design will be revised in embodiments 4 and 5. Specifically, the active region 800 is revised into an active region 610 having two branches 610C and 610D in embodiment 4, and the active region 800 is revised into an active region 610 having three branches 610C, 610D, and 610E in embodiment 5. Jogs 631 and 632 are created as a result of the size difference between the branch segment 610A having a dimension 620A and the segment 610B having a larger dimension 620B in both embodiments 4 and 5. Meanwhile, in both embodiments 4-5, jogs 633 and 634 are also created as a result of the locational offsets between the segment 610B and the branch segments 610C and 610D, respectively, even though the dimensions 620C and 620D of the branch segments 610C and 610D are each smaller than the dimension 620B of the segment 610B. In some embodiments, the dimensions 620A and 620B are each greater than the dimension 810, while the dimensions 620C and 620D is smaller than, or approximately equal to, the dimension 810.

As shown in FIG. 13, whereas a distance 650 separates the branch segments 610C and 610D in embodiment 4, another branch segment 610E (having a dimension 620E) is implemented between the branch segments 610C and 610D in the Y-direction in embodiment 5. Furthermore, a doped-well 850 is also illustrated around the active region 800 in embodiment 5, where a distance 860 separates an edge of the doped-well 850 and the nearest edge of the active region 800 in the original IC layout design. In the revised IC layout design, the doped-well 850 is revised into a doped-well 680 that also surrounds the active region 610. Note that the doped-well 680 in the revised IC layout design also has non-flush edges (e.g., due to the jogs 633 and 634) in the revised IC layout design. However, the same distance 860 is maintained between the edge of the segment 610A and the nearest edge of the doped-well 680, as well as between the edge of the branch segments 610C/610D and the nearest edges of the doped-well 680.

It is understood that when an IC wafer is fabricated using the revised IC layout design of embodiments 4, the resulting active region may appear substantially similar to the active region 610 of FIG. 9 discussed above. When an IC wafer is fabricated using the revised IC layout design of embodiments 5, the resulting active region may appear substantially similar to the active region 610 of FIG. 10 discussed above.

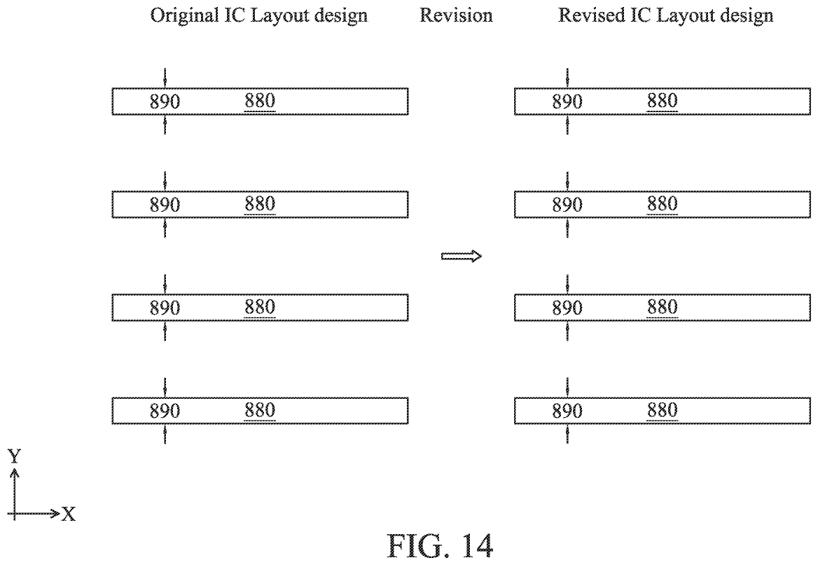

As discussed above, the IC layout revisions may apply to the periphery circuits of the SRAM BitCell region 310, but not to the SRAM BitCell region 310 itself. This aspect is illustrated in FIG. 14, which shows a plurality of example active regions 880 in the SRAM BitCell region 310 before and after the IC layout revision process discussed above has been performed. The active regions 880 in the SRAM BitCell region 310 may appear similar to the active regions 800 of the periphery circuits in some embodiments. For example, the active regions 880 may each assume a substantially rectangular shape with a substantially uniform dimension 890 measured in the Y-direction in the original IC layout design. Since no revision is done to the SRAM BitCell region 310, the revised IC layout design also has the same active regions 880 with the uniform dimensions 890. As discussed above, the independent reconfiguration of the active region 880 is unnecessary in the SRAM BitCell region 310, since the circuitry in the SRAM BitCell region 310 may not need to simultaneously achieve faster speeds in some circuit portions and reduced leakage in other circuit portions.

FIG. 15 illustrates an integrated circuit fabrication system 900 according to embodiments of the present disclosure. The fabrication system 900 includes a plurality of entities 902, 904, 906, 908, 910, 912, 914, 916 . . . , N that are connected by a communications network 918. The network 918 may be a single network or may be a variety of different networks, such as an intranet and the Internet, and may include both wire line and wireless communication channels.

In an embodiment, the entity 902 represents a service system for manufacturing collaboration; the entity 904 represents an user, such as product engineer monitoring the interested products; the entity 906 represents an engineer, such as a processing engineer to control process and the relevant recipes, or an equipment engineer to monitor or tune the conditions and setting of the processing tools; the entity 908 represents a metrology tool for IC testing and measurement; the entity 910 represents a semiconductor processing tool, such an EUV tool that is used to perform lithography processes to define the active regions; the entity 912 represents a virtual metrology module associated with the processing tool 910; the entity 914 represents an advanced processing control module associated with the processing tool 910 and additionally other processing tools; and the entity 916 represents a sampling module associated with the processing tool 910.

Each entity may interact with other entities and may provide integrated circuit fabrication, processing control, and/or calculating capability to and/or receive such capabilities from the other entities. Each entity may also include one or more computer systems for performing calculations and carrying out automations. For example, the advanced processing control module of the entity 914 may include a plurality of computer hardware having software instructions encoded therein. The computer hardware may include hard drives, flash drives, CD-ROMs, RAM memory, display devices (e.g., monitors), input/output device (e.g., mouse and keyboard). The software instructions may be written in any suitable programming language and may be designed to carry out specific tasks.

The integrated circuit fabrication system 900 enables interaction among the entities for the purpose of integrated circuit (IC) manufacturing, as well as the advanced processing control of the IC manufacturing. In an embodiment, the advanced processing control includes adjusting the processing conditions, settings, and/or recipes of one processing tool applicable to the relevant wafers according to the metrology results.

In another embodiment, the metrology results are measured from a subset of processed wafers according to an optimal sampling rate determined based on the process quality and/or product quality. In yet another embodiment, the metrology results are measured from chosen fields and points of the subset of processed wafers according to an optimal sampling field/point determined based on various characteristics of the process quality and/or product quality.

One of the capabilities provided by the IC fabrication system 900 may enable collaboration and information access in such areas as design, engineering, and processing, metrology, and advanced processing control. Another capability provided by the IC fabrication system 900 may integrate systems between facilities, such as between the metrology tool and the processing tool. Such integration enables facilities to coordinate their activities. For example, integrating the metrology tool and the processing tool may enable manufacturing information to be incorporated more efficiently into the fabrication process or the APC module, and may enable wafer data from the online or in site measurement with the metrology tool integrated in the associated processing tool.

FIG. 16 is a flowchart illustrating a method 1000 of revising an IC layout design according to embodiments of the present disclosure. The method 1000 includes a step 1010 to access an integrated circuit (IC) layout design. For example, the IC layout design may be received from an IC design house. In some embodiments, the IC layout design is in the format of a Graphic Data System (GDS) file, which includes solder masks, geometry, layers, component labels, and the general layout of a circuit. The GDS file may have a binary format.

The IC layout design includes a memory-cell circuit and a non-memory-cell circuit. The memory-cell circuit includes a plurality of first active regions. The non-memory-cell circuit includes a plurality of second active regions. The first active regions and the second active regions each extend in a first direction in a top view.

The method 1000 includes a step 1020 to revise the IC layout design at least in part by adjusting a dimension of at least a subset of the second active regions in a second direction different from the first direction in the top view.

The method 1000 includes a step 1030 to fabricate an IC device based on the revised IC layout design.

In some embodiments, the adjusting in the step 1020 is performed without adjusting a dimension to any of the first active regions in the second direction.

In some embodiments, the non-memory-cell circuit includes a first subset of transistors and a second subset of transistors, the first subset of transistors have faster speeds than the second subset of transistors, and the adjusting in the step 1020 is performed at least in part by enlarging the dimension of the second active regions of the first subset of transistors in the second direction.

In some embodiments, the revising the IC layout design of the step 1020 further comprises splitting at least a subset of the second active regions into two or more branches.

In some embodiments, the IC layout design further includes a plurality of well regions disposed around the second active regions, and the revising the IC layout design of the step 1020 further comprises adjusting a dimension of at least a subset of the well regions around the subset of the second active regions, and a distance between edges of the subset of the well regions and edges of the subset of the second active regions remain the same before and after the revising.

In some embodiments, the non-memory-cell circuit includes an input-output circuit, a driver circuit for the memory-cell circuit, a control circuit, or a logic circuit.

It is understood that the method 1000 may include further steps performed before, during, or after the steps 1010-1030. For example, the method 1000 may include steps of performing error checks, etc. For reasons of simplicity, these additional steps are not discussed herein in detail.

The advanced lithography process, method, and materials described above can be used in many applications, including fin-type field effect transistors (FinFETs). For example, the fins may be patterned to produce a relatively close spacing between features, for which the above disclosure is well suited. In addition, spacers used in forming fins of FinFETs, also referred to as mandrels, can be processed according to the above disclosure. It is also understood that the various aspects of the present disclosure discussed above may apply to multi-channel devices such as Gate-All-Around (GAA) devices. To the extent that the present disclosure refers to a fin structure or FinFET devices, such discussions may apply equally to the GAA devices.

In summary, the present disclosure configures the sizes of active regions for non-memory-cell regions of an electronic memory device differently depending on the design and/or manufacturing needs. For example, some segments of the active region may be resized to be larger, while other segments of the active region may be resized to be smaller. Sizing the active regions differently for the non-memory-cell regions of a memory device may offer certain advantages. However, it is understood that not all advantages are discussed herein, different embodiments may offer different advantages, and that no particular advantage is required for any embodiment. One advantage is that the device performance is optimized for the circuit applications corresponding to the differently-resized active regions based on their needs and applications. For example, for some circuits, faster speed is more important. In that case, the active regions in these circuits are resized to have a larger width, which allows faster speeds to be achieved. Meanwhile, for other circuits, reduced leakage is more important. In that case, the active regions in these circuits are resized to have a smaller width, which leads to reduced leakage. In this manner, the non-memory-cell circuits of the electronic memory device can simultaneously achieve faster speed and reduced leakage where these performance criteria are deemed more valuable. It is understood that although these concepts of the present disclosure are discussed using an electronic memory device as an example, they are not intended to be limited to an electronic memory device unless otherwise claimed. The concept of resizing the active regions on an IC device may apply to other suitable IC applications as well. Other advantages may include compatibility with existing fabrication processes (including for both FinFET and GAA processes) and the ease and low cost of implementation.

One aspect of the present disclosure pertains to an electronic memory device. The electronic memory device includes a memory-cell circuit. The electronic memory device also includes a non-memory-cell circuit. The non-memory cell circuit includes an active region. The active region extends in a first direction in a top view. The active region includes a first segment and a second segment. The first segment has a first dimension measured in a second direction in the top view. The second segment has a second dimension measured in the second direction different from the first direction in the top view. The second dimension is different from the first dimension.

One aspect of the present disclosure pertains to a device. The device includes a static random access memory (SRAM) cell array. The device also includes a non-SRAM circuit that includes an active region that extends in a first direction in a top view. The active region includes a first segment and a second segment directly abutting the first segment. The first segment is a part of a first transistor and has a first dimension in a second direction in a top view. The second direction is perpendicular to the first direction. The second segment is a part of a second transistor and has a second dimension in the second direction in the top view. The first transistor is faster than the second transistor. The first dimension is greater than the second dimension.

Yet another aspect of the present disclosure pertains to a method of revising an IC layout design. An integrated circuit (IC) layout design is accessed. The IC layout design includes a memory-cell circuit and a non-memory-cell circuit. The memory-cell circuit includes a plurality of first active regions. The non-memory-cell circuit includes a plurality of second active regions. The first active regions and the second active regions each extend in a first direction in a top view. The IC layout design is revised at least in part by adjusting a dimension of at least a subset of the second active regions in a second direction different from the first direction in the top view.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

The foregoing has outlined features of several embodiments. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

What is claimed is:

1. A device, comprising:
a memory-cell circuit; and
a non-memory-cell circuit that includes an active region;
wherein:
the active region extends in a first direction in a top view;
the active region includes a first segment and a second segment;
the first segment has a first dimension measured in a second direction in the top view;
the second segment has a second dimension measured in the second direction different from the first direction in the top view; and
the second dimension is different from the first dimension.

2. The device of claim 1, wherein the non-memory-cell circuit includes an input-output circuit, a driver circuit for the memory-cell circuit, a control circuit, or a logic circuit.

3. The device of claim 1, wherein:
the first segment of the active region is a part of a first transistor having a first speed;
the second segment of the active region is a part of a second transistor having a second speed faster than the first speed; and
the second dimension is greater than the first dimension.

4. The device of claim 1, wherein:
the active region is a first active region;
the memory-cell circuit has a plurality of second active regions; and
the second active regions have substantially similar dimensions in the second direction.

5. The device of claim 1, wherein:
the first segment has a first edge and a second edge that each extend in the first direction, the first edge and the second edge opposing each other in the second direction;
the second segment has a third edge and a fourth edge that each extend in the first direction, the third edge and the fourth edge opposing each other in the second direction;
the first edge and the third edge are substantially flush with each other; and
a jog exists in the second direction between the second edge and the fourth edge.

6. The device of claim 1, wherein:
the first segment has a first edge and a second edge that each extend in the first direction, the first edge and the second edge opposing each other in the second direction;
the second segment has a third edge and a fourth edge that each extend in the first direction, the third edge and the fourth edge opposing each other in the second direction;
a first jog exists in the second direction between the first edge and the third edge; and
a second jog exists in the second direction between the second edge and the fourth edge.

7. The device of claim 1, wherein:
the active region includes two or more branches that each extends in the first direction; and
the first segment or the second segment is located in one of the branches.

8. The device of claim 7, wherein:
the first segment is located in one of the branches;
the second segment is directly abutting the two or more branches in the first direction; and
the active region further includes a third segment that is directly abutting the second segment in the first direction.

9. The device of claim 8, wherein:
one or more first jogs exist in the second direction between the first segment and the second segment; and
one or more second jogs exist in the second direction between the second segment and the third segment.

10. The device of claim 1, wherein the active region is a part of a vertically-protruding structure of a FinFET device or a gate-all-around (GAA) device.

11. A device, comprising:
a static random access memory (SRAM) cell array; and
a non-SRAM circuit that includes an active region that extends in a first direction in a top view;
wherein:
the active region includes a first segment and a second segment directly abutting the first segment;
the first segment is a part of a first transistor and has a first dimension in a second direction in a top view, the second direction being perpendicular to the first direction;
the second segment is a part of a second transistor and has a second dimension in the second direction in the top view;
the first transistor is faster than the second transistor; and
the first dimension is greater than the second dimension.

12. The device of claim 11, wherein:
the SRAM cell array includes a further active region that extends in the first direction; and
a dimension of the further active region in the second direction is different than the first dimension.

13. The device of claim 11, wherein:
the active region includes a plurality of branches; and
the second segment is located in one of the branches.

14. The device of claim 11, wherein the active region is a part of an input-output circuit, a driver circuit, a control circuit, or a logic circuit.

15. A method, comprising:
accessing an integrated circuit (IC) layout design, wherein the IC layout design includes a memory-cell circuit and a non-memory-cell circuit, wherein the memory-cell circuit includes a plurality of first active regions, wherein the non-memory-cell circuit includes a plurality of second active regions, and wherein the first active regions and the second active regions each extend in a first direction in a top view; and
revising the IC layout design at least in part by adjusting a dimension of at least a subset of the second active regions in a second direction different from the first direction in the top view.

16. The method of claim 15, wherein the adjusting is performed without adjusting a dimension to any of the first active regions in the second direction.

17. The method of claim 15, wherein:
the non-memory-cell circuit includes a first subset of transistors and a second subset of transistors;
the first subset of transistors have faster speeds than the second subset of transistors; and
the adjusting is performed at least in part by enlarging the dimension of the second active regions of the first subset of transistors in the second direction.

18. The method of claim 15, wherein the revising the IC layout design further comprises splitting at least a subset of the second active regions into two or more branches.

19. The method of claim 15, wherein:
the IC layout design further includes a plurality of well regions disposed around the second active regions;
the revising the IC layout design further comprises adjusting a dimension of at least a subset of the well regions around the subset of the second active regions; and
a distance between edges of the subset of the well regions and edges of the subset of the second active regions remain the same before and after the revising.

20. The method of claim 15, wherein the non-memory-cell circuit includes an input-output circuit, a driver circuit for the memory-cell circuit, a control circuit, or a logic circuit.
